(19) United States
(12) Patent Application Publication
(10) Pub. No.: US 2008/0318166 A1
(43) Pub. Date: Dec. 25, 2008

(54) METHOD OF MANUFACTURING SEMICONDUCTOR DEVICE

(76) Inventor: Tsukasa AZUMA, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/143,187

(22) Filed: Jun. 20, 2008

(30) Foreign Application Priority Data
Jun. 20, 2007 (JP) 2007-162403

(51) Int. Cl. H01L 21/02

(52) U.S. Cl. 430/319

(57) ABSTRACT

An object of the present invention is to provide a method of manufacturing semiconductor device, in which a water repellent layer on a resist film surface is removed to improve pattern-size controllability in a developing process. The pattern controllability of a resist pattern is improved by forming the resist pattern in such a manner that a resist film is formed on a surface of a semiconductor substrate, by using an exposure system, a liquid is filled between the resist film and a projection optical system to expose the resist film through the liquid, a water repellent layer formed on a surface of the resist film is removed after exposure, the substrate is thermally-processed after the water repellent layer is remove, and the resist film is developed.

### CROSS-REFERENCE TO RELATED APPLICATIONS

This application is based upon and claims the benefit of priority from the prior Japanese Patent Application No. 2007-162403, filed Jun. 20, 2007, the entire contents of which are incorporated herein by reference.

### BACKGROUND OF THE INVENTION

1. Field of the Invention

The present invention relates to a method of manufacturing semiconductor device.

2. Description of the Related Art

In terms of liquid immersion lithography techniques, the most important issues are to develop liquid immersion exposure systems as well as to develop resist materials for liquid immersion exposure. In particular, there is one type of resist materials for liquid immersion exposure that requires no resist protective film material for protecting a resist film from an immersion liquid. This type of resist materials is effective to reduce cost by simplifying manufacturing processes and also effective to reduce defects caused by liquid immersion. Accordingly, the development of this type of resist materials has been accelerated.

As for a resist process using a liquid immersion exposure system, Japanese Patent Application Publication No. 2007-88256 discloses the technique of trapping an unreacted photo acid generator and the like by supplying an organic-based chemical liquid or the like to a resist film after liquid immersion exposure before a developing process.

### SUMMARY OF THE INVENTION

The present invention has been made to provide a method of manufacturing semiconductor device, in which pattern-size controllability in a developing process is improved.

According to one aspect of the present invention, there can be provided method of manufacturing semiconductor device including the steps of: forming a resist film on a substrate surface; exposing the resist film through liquid filled between the resist film and a projection optical system of an exposure system; removing a water repellent layer of the resist film surface after the exposing step; thermally processing the substrate after the water repellent layer is removed; and forming a resist pattern by developing the resist film.

### BRIEF DESCRIPTION OF THE DRAWINGS

FIGS. 1A to 1E are cross-sectional views showing processes of a method of manufacturing semiconductor device according to an embodiment of the present invention;

FIG. 2 is a flowchart showing the method of manufacturing semiconductor device according to an embodiment of the present invention;

FIG. 3 is a schematic view showing the configuration of a liquid immersion exposure system according an embodiment of the present invention; and

FIGS. 4A to 4E are cross-sectional views showing processes of a method of manufacturing semiconductor device according to an embodiment of the present invention.

### DESCRIPTION OF THE PREFERRED EMBODIMENT method of manufacturing semiconductor device according to an embodiment of the present invention will be described below by referring to the drawings.

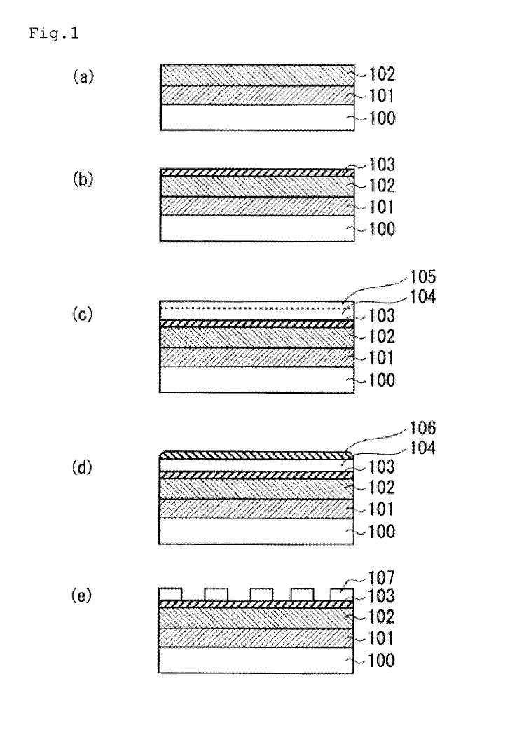

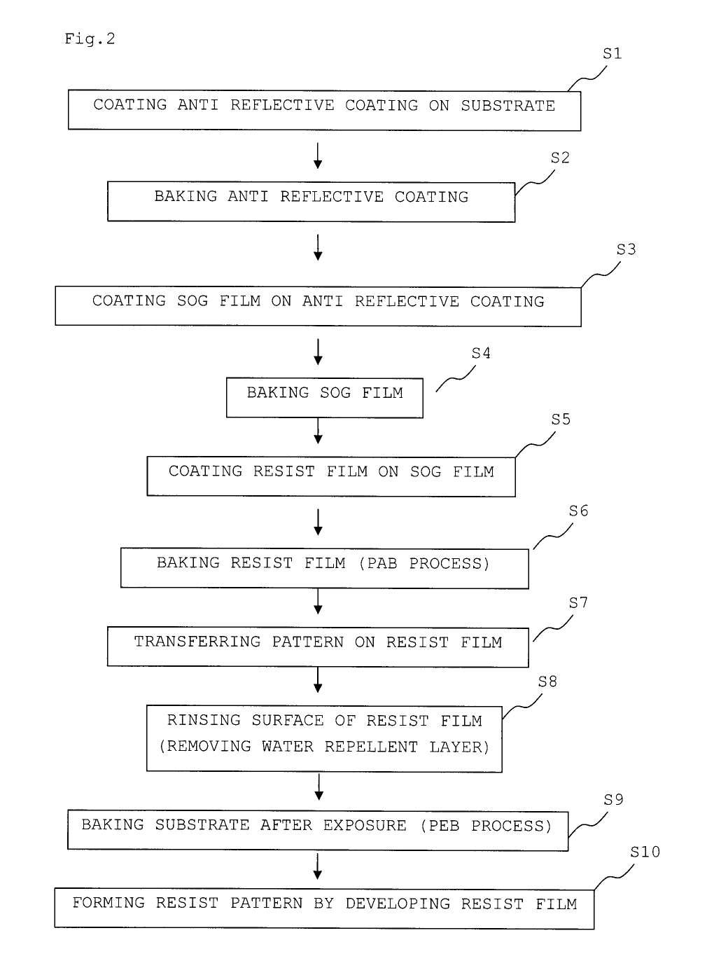

FIGS. 1A to 1E are cross-sectional views showing processes of a pattern forming method according to an embodiment of the present invention. FIG. 2 is a flowchart schematically showing the pattern forming method according to the embodiment of the present invention.

Firstly, as shown in FIG. 1A, an anti reflective coating 102 is spin-coated on a semiconductor substrate 100 by using a coating apparatus (step 1 (S1) in FIG. 2). The anti reflective coating 102 is an organic film with a film-thickness of approximately 300 nm, and the semiconductor substrate 100 is a silicon wafer with the diameter of 300 mm. A processed film 101, such as an insulating layer, is formed on the substrate 100 surface. In addition, the anti reflective coating 102 is firstly applied to the substrate 100, and then the substrate 100 is thermally processed in film-forming processing in a two-step baking process (step 2 (S2) in FIG. 2) including a first bake at 180° C. for 60 seconds and a second bake at 300° C. for 60 seconds.

Subsequently, as shown in FIG. 1B, an SOG film 103, which is mainly formed of polysiloxane, with a film-thickness of approximately 45 nm is spin-coated on the anti reflective coating 102 (step 3 (S3) in FIG. 2). After being coated on the anti reflective coating 102, the SOG film 103 is processed in film-forming processing in a two-step baking process (Step 4 (S4) in FIG. 2) including a first bake at 180° C. for 60 seconds, and a second bake at 300° C. for 60 seconds.

Thereafter, as shown in FIG. 1C, a resist film 104 with a film-thickness of approximately 100 nm is coated on the SOG film 103 (step 5 (S5) in FIG. 2). The resist film 104 is subjected to film-forming processing in which, after being coated on the SOG film, the resist film 104 is baked at the temperature of 90° C. for the processing time of 60 seconds (PAB (Post Apply Bake) processing) (step 6 (S6) in FIG. 2).

The resist film 104 used in the present embodiment is a chemically-amplified resist (topcoatless resist) used for liquid immersion exposure. In addition, a thin water repellent layer 105 is formed of the surface portion of the resist film 104. Accordingly, when a circuit pattern is exposed onto the resist film 104 by using an liquid immersion exposure system, an immersion liquid can be prevented from penetrating into the resist film 104 even if a protective film for preventing the immersion liquid, such as pure water (deionized water), from penetrating into the resist film 104, is not formed on the resist film 104. On the other hand, the resist film 104 is designed so as to be nonrepellent to a developer. Thereby, an exposed portion of the resist film 104 can be easily dissolved by supplying a developer, and thus a resist pattern can be formed.

Next, a liquid immersion exposure system with the numerical aperture of approximately 1.2 NA is used to transfer the semiconductor circuit pattern onto the resist film 104 on the substrate 100 (step 7 (S7) in FIG. 2). The semiconductor circuit pattern is a line-and-space (L/S) semiconductor circuit pattern with the minimum line width of 45 nm.

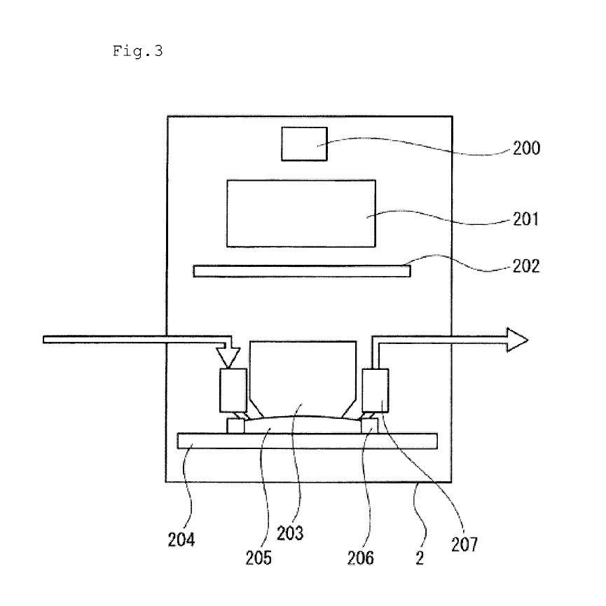

Here, the configuration of the liquid immersion exposure system according to the present embodiment will be described by referring to FIG. 3. FIG. 3 is a schematic view showing the configuration of the liquid immersion exposure system according to the present embodiment.

A liquid immersion exposure system 2 includes: an ArF excimer laser (with the wavelength λ=193 nm) light source 200; a lighting optical system 201; and a reticle stage 202 below the illumination optical system 201. When the circuit pattern is transferred to the resist film formed on the semiconductor substrate 100, a reticle being a photo mask in which a mask pattern is formed is placed on the reticle stage 202. Then, exposure light emitted from the light source 200 is gathered by the illumination optical system 201 to irradiate the mask.

A projection optical system 203 is placed below the reticle stage 202 and a wafer stage 204 is placed below the projection optical system 203 for placing the semiconductor substrate. Through the projection optical system 203, the exposure light emitted to the mask is caused to form an image on the surface of the resist film on the surface of the substrate placed on the wafer stage 204. Thereby, the mask pattern formed on the mask is transferred to the resist film on the surface of the substrate.

On the wafer stage 204 below the projection optical system 203, a fence 206 is attached for keeping a liquid 205 for liquid immersion exposure (immersion liquid 205) or the like to be supplied to the wafer stage 204. At the time of exposure, a layer of the immersion liquid 205 with a thickness of approximately 100 μm is filled in an area for an optical path in a region surrounded by the fence 206, in which the substrate 100 and the projection optical system 203 face each other. And, during exposure, the immersion liquid 205 contacts the resist film on the substrate and the projection optical system 203.

A pair of heads 207 are provided, in a vicinity of the projection optical system 203, for carrying out injection of the immersion liquid 205 into the inside of the fence 206 and retrieval of the immersion liquid 205 from the inside of the fence 206.

The exposure system 2 having the above-described configuration allows the liquid 205 to be filled between the resist film 104 and the projection optical system 203 and the resist film 104 to be exposed through the liquid 205 to transfer a pattern onto the resist film 104.

As shown in FIG. 1D, after the pattern is transferred to the resist film 104, an alkaline aqueous solution 106, for example, a TMAH (tetramethylammonium hydroxide) organic alkaline aqueous solution 106 with 0.238 weight percent is supplied to the resist film 104 on the surface of the substrate by using a coating applicator, while rotating the substrate 100 mounted on a stage of the coating applicator. Thereby, a surface rinsing process, which is referred to as a post-soak process, is carried out (step 8 (S8) in FIG. 2).

In the surface rinsing process, the organic alkaline aqueous solution 106 is supplied to the surface of the resist film 104, so that the water repellent layer 105 formed of the surface of the resist film 104 can be dissolved and removed. Here, the concentration of the TMAH organic alkaline aqueous solution 106 is reduced to be a proper value. Thereby, the exposed portion of the resist pattern 104 is prevented from being developed to form a resist pattern 107.

In the present embodiment, the TMAH organic alkaline aqueous solution 106 with 0.238 weight percent is supplied to the surface of the resist film 104 in order to remove the water repellent layer 105. However, such a method is not necessarily needed to remove the water repellent layer 105. The water repellent layer 105 on the surface of the resist layer 104 can be properly removed by properly adjusting the type, concentration, amount of the solution to be supplied to the resist layer 104 depending on the type of the resist film 104 or the type and thickness of the water repellent layer 105.

Next, as shown in FIG. 1E, the semiconductor substrate 100 is subjected to PEB (Post Exposure Bake) processing at the temperature of 115° C. for the processing time of 60 seconds by using a hotplate or the like (step 9 (S9) in FIG. 2). Subsequently, the TMAH organic alkaline aqueous solution 106 with 2.38 weight percent is supplied to the resist film 104 mounted on the stage by using the coating device. Thereby, the resist film 104 is developed to form an L/S resist pattern 107 with the minimum line width of 45 nm (step 10 (S10) in FIG. 2).

The TMAH organic alkaline aqueous solution 106 used in the developing process is the same type of the chemical solution as that used for removing the water repellent layer 105 of the surface layer of the resist film 104, but is adjusted to have a higher concentration of organic alkali than that used for removing the water repellent layer 105. When this developer with such a high concentration is used, the exposed portion of the pattern on the resist film 104 can be sufficiently dissolved. Thereby, a dimensionally-controlled resist pattern 107 can be formed. Note that the developing process is not necessarily carried out by using, as a developer, the same chemical solution as that used for removing the water repellent layer 105.

In general, in the process of developing the resist film, if a surface of a resist film is water repellent, it is likely to be caused that the speed of dissolving the resist film by using a developer becomes difficult to be uniformly controlled throughout the entire pattern to be formed. In other words, the speed of dissolving the resist film varies depending on differences in size, arrangement or density among portions of a pattern to be formed on the resist film. Such dissolving speed variation causes unevenness in the developed pattern depending on the partial difference in the pattern size and the pattern density, and variations in the development progress among the inner ends of the pattern. Thus, there is caused a problem that extremely deteriorates the pattern-size controllability of the resist pattern.

In contrast, in the pattern forming method according to the present embodiment, an alkaline aqueous solution 106 with low-concentration is used to carry out a surface rising process on the resist film 104 after being exposed, so that the water repellent layer 105 of the resist film 104 surface is removed. As described above, the water repellent layer 105 of the resist film 104 surface is removed. Thereby, in the developing process, the resist film 104 can be developed without having the water repellent layer 105 thereon, which leads to improvement by reducing the pattern size/density dependence and variations in the development progress among patterns formed on the inner and outer of substrate.

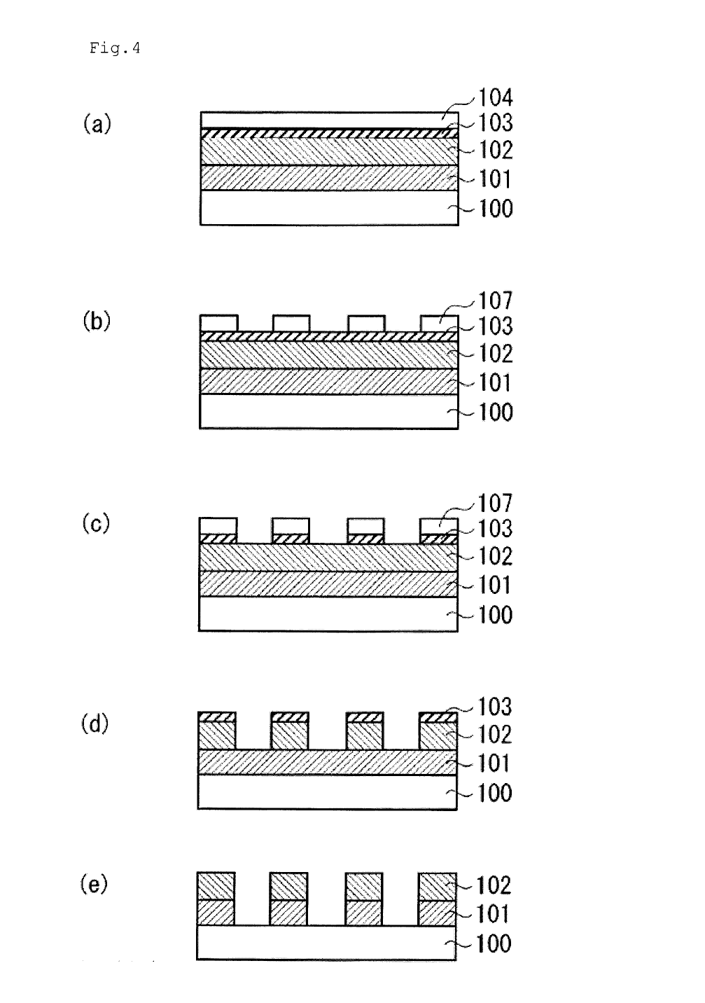

In addition, a semiconductor device can be manufactured by using the pattern forming method according to the present embodiment. A semiconductor device manufacturing method according to the present embodiment will be described below by referring to FIG. 4. FIGS. 4A to 4E are cross-sectional views showing a semiconductor device manufacturing method according to the present embodiment.

Firstly, as shown in FIG. 4A, a anti reflective coating 102, an SOG film 103, and a resist film 104 are coated in this order on a semiconductor substrate 100 on which a processed film 101 is formed in advance on the surface thereof. Then, each of the films is baked.

Subsequently, as shown in FIG. 4B, a resist pattern 107 is formed on the substrate 100 by using the above-described pattern forming method according to the above-described present embodiment. If a gate pattern structure of a NAND flash memory is formed by using the pattern forming method according to the present embodiment, the resist pattern 107 is formed so as to be, for example, an L/S pattern with the line width of 45 nm.

After that, as shown in FIG. 4C, by using the resist pattern 107 as a mask, the exposed SOG film 103 formed thereunder is etched by RIE (Reactive Ion Etching).

Then, as shown in FIG. 4D, the resist pattern 107 is removed by ashing using oxygen plasmas or the like. Thereafter, by using the SOG film 103 as a mask, the exposed anti reflective coating 102 formed thereunder is etched by RIE.

Furthermore, as shown in FIG. 4E, after the SOG film is removed, by using the anti reflective coating 102 as a mask, the processed film 101 on the semiconductor substrate 100 surface is etched by RIE.

Thereby, the processed film 101 on the semiconductor substrate 100 surface, for example, a polysilicon film can be processed so as to be an L/S pattern with the line width of 45 nm.

In the present embodiment, a pattern is exposed onto the resist film 104 at the time of forming the resist pattern 107, and thereafter the organic alkaline aqueous solution 106 is supplied to the resist film 104 before the resist film 104 is developed. Thereby, the water repellent layer 105 is removed. Thus, the pattern controllability, such as the pattern size/density dependence or the variations in the development progress among patterns formed on the inner and outer of substrate, can be improved.

Accordingly, the process controllability of the processed film 101 can be also improved in the semiconductor device manufacturing device, and a finer pattern of the processed film, for example, a gate pattern of a NAND flash memory can be processed.

Note that in the semiconductor device manufacturing method according to the present embodiment, the SOG film 103 and the anti reflective coating 102 are formed as lower layer films of the resist film 104 and these films are processed. However, the resist film 104 may be directly formed on the processed film 101 without forming the SOG film or/and the anti reflective coating 102. In this case, a processed film pattern is formed by etching the processed film 101 formed in the lower layer by using the resist pattern 107 as a mask.

What is claimed is:

1. A method of manufacturing semiconductor device comprising:
forming a resist film on a substrate surface;
exposing the resist film through liquid filled between the resist film and a projection optical system using an exposure system;
removing a water repellent layer of the resist film surface after the exposing step;
thermally processing the substrate after the water repellent layer is removed; and
forming a resist pattern by developing the resist film.

2. A method according to claim 1, wherein the step of the removing the water repellent layer comprising rinsing the resist film surface by providing an alkali solution to the resist film surface.

3. A method according to claim 2, wherein the alkali solution is an organic alkali aqueous solution.

4. A method according to claim 3, wherein a concentration of the organic alkali in the organic alkali aqueous solution used for removing the water repellent layer is lower than that of an organic alkali in the organic alkali aqueous solution used for developing the resist film.

5. A method according to claim 1, wherein the liquid is deionized water.

6. A method according to claim 1, wherein the liquid contacts the resist film in the exposure step.
